(19) United States
(12) Patent Application Publication
(10) Pub. No.: US 2024/0038558 A1
(43) Pub. Date: Feb. 1, 2024

(54) METROLOGY SAMPLING PLANS FOR ONLY OUT OF SPECIFICATION DETECTION

(71) Applicant: KLA Corporation, Milpitas, CA (US)

(72) Inventors: Fatima Anis, San Jose, CA (US); Irina Brinster, Austin, TX (US)

(21) Appl. No.: 18/353,098

(22) Filed: Jul. 16, 2023

Related U.S. Application Data
(60) Provisional application No. 63/392,126, filed on Jul. 26, 2022.

(51) Int. Cl. H01L 21/67; G01N 35/00

(52) U.S. Cl. CPC H01L 21/67288; G01N 35/00584

(57) ABSTRACT

Methods and systems for determining information for a specimen are provided. One method includes generating a sampling plan for only out of specification detection of a characteristic of specimens in a metrology process. The method also includes generating output for the specimens by performing the metrology process on the specimens with the generated sampling plan. In addition, the method includes determining the characteristic of the specimen based on the generated output and detecting if the characteristic of one or more of the specimens is out of specification based on the determined characteristic of the specimens. The embodiments described herein are particularly suitable for overlay metrology with substantially sparse sampling plans configured for only out of specification detection of the overlay.

### BACKGROUND OF THE INVENTION

### 1. Field of the Invention

The present invention generally relates to methods and systems configured for determining information for a specimen. Certain embodiments relate to methods and systems for generating and using sampling plans designed specifically for only detecting out of specification specimens.

### 2. Description of the Related Art

The following description and examples are not admitted to be prior art by virtue of their inclusion in this section.

Fabricating semiconductor devices such as logic and memory devices typically includes processing a substrate such as a semiconductor wafer using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etch, deposition, and ion implantation. Multiple semiconductor devices may be fabricated in an arrangement on a single semiconductor wafer and then separated into individual semiconductor devices.

Inspection processes are used at various steps during a semiconductor manufacturing process to detect defects on wafers to promote higher yield in the manufacturing process and thus higher profits. Inspection has always been an important part of fabricating semiconductor devices such as ICs. However, as the dimensions of semiconductor devices decrease, inspection becomes even more important to the successful manufacture of acceptable semiconductor devices because smaller defects can cause the devices to fail.

Defect review typically involves re-detecting defects detected as such by an inspection process and generating additional information about the defects at a higher resolution using either a high magnification optical system or a scanning electron microscope (SEM). Defect review is therefore performed at discrete locations on the wafer where defects have been detected by inspection. The higher resolution data for the defects generated by defect review is more suitable for determining attributes of the defects such as profile, roughness, more accurate size information, etc.

Metrology processes are also used at various steps during a semiconductor manufacturing process to monitor and control the process. Metrology processes are different than inspection processes in that, unlike inspection processes in which defects are detected on a wafer, metrology processes are used to measure one or more characteristics of the wafer that cannot be determined using currently used inspection tools. For example, metrology processes are used to measure one or more characteristics of a wafer such as a dimension (e.g., line width, thickness, etc.) of features formed on the wafer during a process such that the performance of the process can be determined from the one or more characteristics. In addition, if the one or more characteristics of the wafer are unacceptable (e.g., out of a predetermined range for the characteristic(s)), the measurements of the one or more characteristics of the wafer may be used to alter one or more parameters of the process such that additional wafers manufactured by the process have acceptable characteristic(s).

Metrology processes are also different than defect review processes in that, unlike defect review processes in which defects that are detected by inspection are re-visited in defect review, metrology processes may be performed at locations at which no defect has been detected. In other words, unlike defect review, the locations at which a metrology process is performed on a wafer may be independent of the results of an inspection process performed on the wafer. In particular, the locations at which a metrology process is performed may be selected independently of inspection results. In addition, since locations on the wafer at which metrology is performed may be selected independently of inspection results, unlike defect review in which the locations on the wafer at which defect review is to be performed cannot be determined until the inspection results for the wafer are generated and available for use, the locations at which the metrology process is performed may be determined before an inspection process has been performed on the wafer.

For all of the yield-related processes described above, it would be advantageous to inspect, review, and measure every possible point on every possible specimen. Of course, this is not practical or desired because of the time and cost that such sampling would entail. Therefore, selecting which points, locations, areas, etc. on a specimen to inspect, review, measure, i.e., sampling, is a critical aspect of creating yield-related process recipes that generate results that are sufficient for monitoring and/or controlling the process while minimizing the time and cost needed to generate the results. Some more time-intensive processes like metrology can make this sampling much more difficult. For example, it can be extremely difficult to find the appropriate tradeoff point between expeditious and affordable metrology results that also provide enough data for proper detection of an out of specification process and/or feedback control of the process.

For metrology, sampling methods and systems in the fab must make a number of decisions such as which lots to measure, which wafers within the lots to measure, and which points on the wafer to measure. The sampling decision involves a tradeoff between the required throughput of the process and the criticality or impact of the process step on the yield. In the fab, overlay metrology serves two primary purposes, run to run (R2R) control and out of specification detection, where a run may be a lot or multiple lots depending on how critical the layers are. These objectives often conflict with each other because the measurements performed for out of specification detection may not be sufficient for R2R control and the R2R control measurements may have a throughput that is too slow to make the measurements viable for adequate out of specification detection. Therefore, designing an overlay metrology process often involves a tradeoff between the two objectives.

Currently, the performance of these two tasks is not separated from each other. Depending on the layer and device, the trend is to measure 2-4 wafers per lot densely with enough measurement points to perform feedback control. In other words, in currently used methods, only a subset of lots and a substantially small subset of wafers within the subset of lots is measured with a full process of record (POR) sampling plan to update process tool (e.g., scanner) corrections for advanced process control (APC) and detect out of specification wafers. In this manner, currently used methods are designed for APC which also allows the results to be used for some out of specification detection. If a measured wafer or lot does not satisfy the predefined in-specification requirements, it is sent for rework. For more critical layers, each lot may be measured. For less critical layers, a random selection of lots is performed.

There are a number of important disadvantages to the currently used methods for overlay metrology and sampling. For example, the currently used methods can miss out of specification lots due to random lot selection, which can result in reduced yield. In other words, if lots are selected randomly for metrology, some out of specification lots may not be detected and may proceed to the next process steps resulting in yield loss. In another example, the currently used methods can miss out of specification lots due to “lucky” wafers selected for the measurement within the lot. If a relatively small number of wafers is measured per lot, they may not be representative of the whole lot. In particular, these wafers may be in specification, while most of the other wafers may be out of specification. In an additional example, the currently used methods may cause false detection and rework if “unlucky” wafers are selected within the lot. In the worst case, “unlucky” wafers can cause an in specification lot to go out of specification after rework. In particular, if a relatively small number of wafers is measured per lot, these wafers may not be representative of the whole lot. These measured wafers may be out of specification, while most of the non-measured wafers may be in specification. In this case, the corrections used for rework are calculated using the non-representative wafers. When the lot is reworked, the measured wafers are fixed, but the rest of the wafers within the lot may degrade and may go out of specification. In a further example, the currently used methods do not consider co-optimization of metrology tool settings and sampling to achieve higher throughput.

Accordingly, it would be advantageous to develop systems and methods for generating and using metrology sampling plans for only out of specification detection that do not have one or more of the disadvantages described above.

### SUMMARY OF THE INVENTION

The following description of various embodiments is not to be construed in any way as limiting the subject matter of the appended claims.

One embodiment relates to a system configured for determining information for a specimen. The system includes a computer system configured for generating a sampling plan for only out of specification detection of a characteristic of specimens in a metrology process. The system also includes a metrology subsystem configured for generating output for the specimens by performing the metrology process on the specimens with the generated sampling plan. The computer subsystem is also configured for determining the characteristic of the specimens based on the generated output and detecting if the characteristic of one or more of the specimens is out of specification based on the determined characteristic of the specimens. The system may be further configured as described herein.

Another embodiment relates to a computer-implemented method for determining information for a specimen. The method includes generating a sampling plan for only out of specification detection of a characteristic of specimens in a metrology process and generating output for the specimens by performing the metrology process on the specimens with a metrology subsystem and the generated sampling plan. The method also includes determining the characteristic of the specimens based on the generated output and detecting if the characteristic of one or more of the specimens is out of specification based on the determined characteristic of the specimens. Generating the sampling plan, determining the characteristic, and the detecting step are performed by a computer system coupled to the metrology subsystem.

The steps of the method may be performed as described herein. In addition, the method may include any other step(s) of any other method(s) described herein. Furthermore, the method may be performed by any of the systems described herein.

Another embodiment relates to a non-transitory computer-readable medium storing program instructions executable on one or more computer systems for performing a computer-implemented method for determining information for a specimen. The computer-implemented method includes the steps of the method described above. The computer-readable medium may be further configured as described herein. The steps of the computer-implemented method may be performed as described further herein. In addition, the computer-implemented method for which the program instructions are executable may include any other step(s) of any other method(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIGS. 1 and 2 are schematic diagrams illustrating side views of embodiments of a system configured as described herein;

FIG. 3 is a flow chart illustrating one embodiment of a method for determining information for a specimen; and

FIG. 4 is a block diagram illustrating one embodiment of a non-transitory computer-readable medium storing program instructions for causing a computer system to perform a computer-implemented method described herein.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals. Unless otherwise noted herein, any of the elements described and shown may include any suitable commercially available elements.

In general, the embodiments described herein relate to methods and systems for determining information for a specimen. Some embodiments described herein are configured for extremely sparse sampling methods for detecting out of specification specimens, e.g., wafers, and lots.

In one embodiment, the specimens are wafers. The wafers may include any wafers known in the semiconductor arts. Although some embodiments may be described herein with respect to wafers, the embodiments are not limited in the specimens for which they can be used. For example, the embodiments described herein may be used for specimens such as reticles, flat panels, personal computer (PC) boards, and other semiconductor specimens.

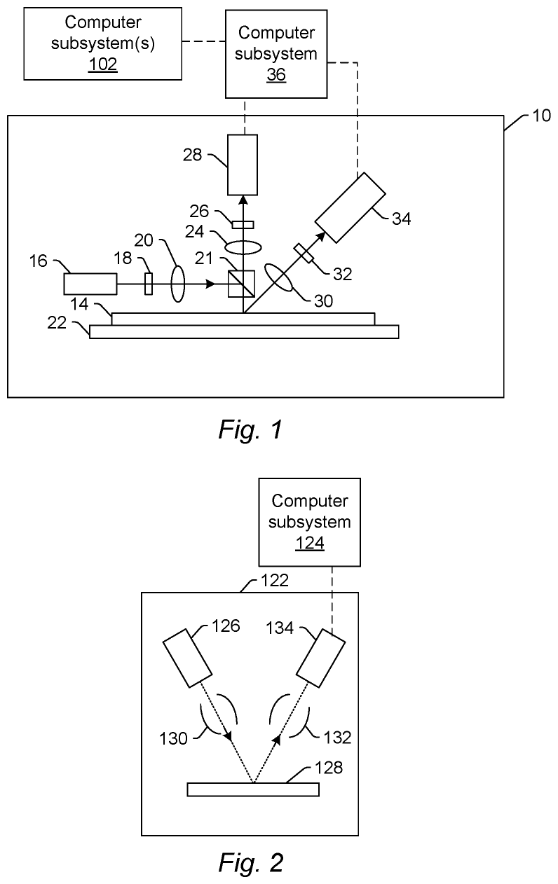

One embodiment of a system configured for determining information for a specimen is shown in FIG. 1. The system includes metrology subsystem 10 that includes at least an energy source and a detector. The energy source is configured to generate energy that is directed to a wafer. The detector is configured to detect energy from the wafer and to generate output responsive to the detected energy.

In one embodiment, the metrology subsystem is configured as a light-based metrology subsystem. For example, as system shown in FIG. 1, metrology subsystem 10 includes an illumination subsystem configured to direct light to wafer 14. The illumination subsystem includes at least one light source, e.g., light source 16. The illumination subsystem is configured to direct the light to the wafer at one or more angles of incidence, which may include one or more oblique angles and/or one or more normal angles. For example, as shown in FIG. 1, light from light source 16 is directed through optical element 18 and then lens 20 to beam splitter 21, which directs the light to wafer 14 at a normal angle of incidence. The angle of incidence may include any suitable angle of incidence, which may vary depending on, for instance, characteristics of the wafer.

The illumination subsystem may be configured to direct the light to the wafer at different angles of incidence at different times. For example, the metrology subsystem may be configured to alter one or more characteristics of one or more elements of the illumination subsystem such that the light can be directed to the wafer at an angle of incidence that is different than that shown in FIG. 1. In one such example, the metrology subsystem may be configured to move light source 16, optical element 18, and lens 20 such that the light is directed to the wafer at a different angle of incidence.

The metrology subsystem may be configured to direct light to the wafer at more than one angle of incidence at the same time. For example, the illumination subsystem may include more than one illumination channel, one of the illumination channels may include light source 16, optical element 18, and lens 20 as shown in FIG. 1 and another of the illumination channels (not shown) may include similar elements, which may be configured differently or the same, or may include at least a light source and possibly one or more other components such as those described further herein. If such light is directed to the wafer at the same time as the other light, one or more characteristics (e.g., wavelength, polarization, etc.) of the light directed to the wafer at different angles of incidence may be different such that light resulting from illumination of the wafer at the different angles of incidence can be discriminated from each other at the detector(s).

The illumination subsystem may also include only one light source (e.g., source 16 shown in FIG. 1) and light from the light source may be separated into different optical paths (e.g., based on wavelength, polarization, etc.) by one or more optical elements (not shown) of the illumination subsystem. Light in each of the different optical paths may then be directed to the wafer. Multiple illumination channels may be configured to direct light to the wafer at the same time or at different times (e.g., when different illumination channels are used to sequentially illuminate the wafer). In another instance, the same illumination channel may be configured to direct light to the wafer with different characteristics at different times. For example, in some instances, optical element 18 may be configured as a spectral filter and the properties of the spectral filter can be changed in a variety of different ways (e.g., by swapping out the spectral filter) such that different wavelengths of light can be directed to the wafer at different times. The illumination subsystem may have any other suitable configuration known in the art.

Light source 16 may be a broadband plasma (BBP) light source. In this manner, the light generated by the light source and directed to the wafer may include broadband light. However, the light source may include any other suitable light source such as any suitable laser known in the art configured to generate light at any suitable wavelength(s) known in the art. The laser may be configured to generate light that is monochromatic or nearly-monochromatic. In this manner, the laser may be a narrowband laser. The light source may also include a polychromatic light source that generates light at multiple discrete wavelengths or wavebands.

Light from optical element 18 may be focused to beam splitter 21 by lens 20. Although lens 20 is shown in FIG. 1 as a single refractive optical element, in practice, lens 20 may include a number of refractive and/or reflective optical elements that in combination focus the light from the optical element to the wafer. The illumination subsystem may include any other suitable optical elements (not shown). Examples of such optical elements include, but are not limited to, polarizing component(s), spectral filter(s), spatial filter(s), reflective optical element(s), apodizer(s), beam splitter(s), aperture(s), and the like, which may include any such suitable optical elements known in the art. In addition, the system may be configured to alter one or more of the elements of the illumination subsystem based on the type of illumination to be used for the wafer.

The metrology subsystem may also include a scanning subsystem configured to move the wafer relative to the optical elements. For example, the metrology subsystem may include stage 22 on which wafer 14 is disposed during metrology. The scanning subsystem may include any suitable mechanical and/or robotic assembly (that includes stage 22) that can be configured to move the wafer such that one or more different measurement points on the wafer can be positioned in the field of view of the metrology subsystem. In addition, or alternatively, the metrology subsystem may be configured such that one or more optical elements of the metrology subsystem move relative to the wafer to thereby measure different points on the wafer. The wafer may be moved relative to the metrology subsystem (or vice verse) in any suitable fashion.

The metrology subsystem further includes one or more detection channels. At least one of the detection channel(s) includes a detector configured to detect light from the wafer due to illumination of the wafer by the metrology subsystem and to generate output responsive to the detected light. For example, the metrology subsystem shown in FIG. 1 includes two detection channels, one formed by collector 24, element 26, and detector 28 and another formed by collector 30, element 32, and detector 34. As shown in FIG. 1, the two detection channels are configured to collect and detect light at different angles of collection. In some instances, one detection channel is configured to detect specularly reflected light, and the other detection channel is configured to detect light that is not specularly reflected (e.g., scattered, diffracted, etc.) from the wafer. However, the detection channels may be configured to detect the same type of light from the wafer (e.g., specularly reflected light). The metrology subsystem may also include a different number of detection channels (e.g., only one detection channel or two or more detection channels). Although each of the collectors are shown in FIG. 1 as single refractive optical elements, each of the collectors may include refractive optical element(s) and/or reflective optical element(s).

The detection channels may include any suitable detectors known in the art such as photo-multiplier tubes (PMTs), charge coupled devices (CCDs), and time delay integration (TDI) cameras. The detectors may also include non-imaging detectors or imaging detectors. Non-imaging detectors may be configured to detect certain characteristics of the light such as intensity but may not be configured to detect such characteristics as a function of position within the imaging plane. The output generated by such detectors may be signals or data, but not image signals or image data. In such instances, a computer subsystem such as computer subsystem 36 of the system may be configured to generate images of the wafer from the non-imaging output of the detectors. However, the detectors may be configured as imaging detectors that are configured to generate imaging signals or image data. Therefore, the system may be configured to generate the output described herein in a number of ways.

FIG. 1 is provided herein to generally illustrate a configuration of a metrology subsystem that may be included in the system embodiments described herein. Obviously, the metrology subsystem configuration described herein may be altered to optimize the performance of the system as is normally performed when designing a commercial system. In addition, the systems described herein may be implemented using an existing metrology system (e.g., by adding functionality described herein to an existing system) such as the Archer, ATL, SpectraShape, SpectraFilm, Aleris, and WaferSight series of tools that are commercially available from KLA Corp., Milpitas, Calif. For some such systems, the methods described herein may be provided as optional functionality of the system (e.g., in addition to other functionality of the system). Alternatively, the system described herein may be designed “from scratch” to provide a completely new system.

Computer subsystem 36 of the system may be coupled to the detectors of the metrology subsystem in any suitable manner (e.g., via one or more transmission media, which may include “wired” and/or “wireless” transmission media) such that the computer subsystem can receive the output generated by the detectors during metrology. Computer subsystem 36 may be configured to perform a number of functions using the output of the detectors as described herein and any other functions described further herein. For example, the computer subsystem may be configured for determining a characteristic of the specimens based on the generated output.

The characteristic of the specimens determined by the computer subsystem may vary depending on the configuration of the metrology subsystem and the specimens being measured. In one embodiment, the characteristic is overlay of one or more first patterned features formed on the specimen to one or more second patterned features formed on the specimen. The characteristic of the specimens may be any other characteristic of interest such as film thickness, patterned structure profile, critical dimension (CD), line edge roughness (LER), and line width roughness (LWR). These characteristics may be determined using the generated output in any manner known in the art. This computer subsystem may be further configured as described herein.

This computer subsystem (as well as other computer subsystems described herein) may also be referred to herein as computer system(s). Each of the computer subsystem(s) or system(s) described herein may take various forms, including a personal computer system, image computer, mainframe computer system, workstation, network appliance, Internet appliance, or other device. In general, the term “computer system” may be broadly defined to encompass any device having one or more processors, which executes instructions from a memory medium. The computer subsystem(s) or system(s) may also include any suitable processor known in the art such as a parallel processor. In addition, the computer subsystem(s) or system(s) may include a computer platform with high speed processing and software, either as a standalone or a networked tool.

If the system includes more than one computer subsystem, then the different computer subsystems may be coupled to each other such that images, data, information, instructions, etc. can be sent between the computer subsystems as described further herein. For example, computer subsystem 36 may be coupled to computer subsystem(s) 102 (as shown by the dashed line in FIG. 1) by any suitable transmission media, which may include any suitable wired and/or wireless transmission media known in the art. Two or more of such computer subsystems may also be effectively coupled by a shared computer-readable storage medium (not shown).

In another embodiment, the metrology subsystem is configured as an electron beam metrology subsystem. In one such embodiment shown in FIG. 2, the metrology subsystem includes electron column 122, which is coupled to computer subsystem 124. As also shown in FIG. 2, the electron column includes electron beam source 126 configured to generate electrons that are focused to wafer 128 by one or more elements 130. The electron beam source may include, for example, a cathode source or emitter tip, and one or more elements 130 may include, for example, a gun lens, an anode, a beam limiting aperture, a gate valve, a beam current selection aperture, an objective lens, and a scanning subsystem, all of which may include any such suitable elements known in the art.

Electrons returned from the wafer (e.g., secondary electrons) may be focused by one or more elements 132 to detector 134. One or more elements 132 may include, for example, a scanning subsystem, which may be the same scanning subsystem included in element(s) 130.

The electron column may include any other suitable elements known in the art. In addition, the electron column may be further configured as described in U.S. Pat. No. 8,664,594 issued Apr. 4, 2014 to Jiang et al., U.S. Pat. No. 8,692,204 issued Apr. 8, 2014 to Kojima et al., U.S. Pat. No. 8,698,093 issued Apr. 15, 2014 to Gubbens et al., and U.S. Pat. No. 8,716,662 issued May 6, 2014 to MacDonald et al., which are incorporated by reference as if fully set forth herein.

Although the electron column is shown in FIG. 2 as being configured such that the electrons are directed to the wafer at an oblique angle of incidence and collected from the wafer at another oblique angle, the electron beam may be directed to and collected from the wafer at any suitable angles. In addition, the metrology subsystem may be configured to use multiple modes to generate output for the wafer (e.g., with different illumination angles, collection angles, etc.). The multiple modes of the metrology subsystem may be different in any image generation parameters of the subsystem.

Computer subsystem 124 may be coupled to detector 134 as described above. The detector may detect electrons returned from the surface of the wafer thereby forming electron beam images of the wafer. The electron beam images may include any suitable electron beam images. Computer subsystem 124 may be configured to perform any of the functions described herein using the output of the detector and/or the electron beam images. Computer subsystem 124 may be configured to perform any additional step(s) described herein. A system that includes the electron beam subsystem shown in FIG. 2 may be further configured as described herein.

FIG. 2 is provided herein to generally illustrate a configuration of an metrology subsystem that may be included in the embodiments described herein. As with the optical subsystem described above, the electron beam subsystem described herein may be altered to optimize the performance of the metrology subsystem as is normally performed when designing a commercial system. In addition, the systems described herein may be implemented using an existing electron beam system (e.g., by adding functionality described herein to an existing electron beam system). For some such systems, the methods described herein may be provided as optional functionality of the system (e.g., in addition to other functionality of the system). Alternatively, the system described herein may be designed “from scratch” to provide a completely new system.

Although the metrology subsystem is described above as being an optical or electron beam subsystem, the metrology subsystem may be an ion beam subsystem. Such a metrology subsystem may be configured as shown in FIG. 2 except that the electron beam source may be replaced with any suitable ion beam source known in the art. In addition, the metrology subsystem may be any other suitable ion beam tool such as those included in commercially available focused ion beam (FIB) systems, helium ion microscopy (HIM) systems, and secondary ion mass spectroscopy (SIMS) systems.

As noted above, the metrology subsystem is configured for directing energy (e.g., light, electrons, etc.) to a physical version of the specimen thereby generating output for the physical version of the specimen. In this manner, the metrology subsystem may be configured as an “actual” subsystem, rather than a “virtual” subsystem. However, a storage medium (not shown) and computer system(s) 102 shown in FIG. 1 may be configured as a “virtual” system. In particular, the storage medium and the computer subsystem(s) may be configured as a “virtual” system as described in commonly assigned U.S. Pat. No. 8,126,255 issued on Feb. 28, 2012 to Bhaskar et al. and U.S. Pat. No. 9,222,895 issued on Dec. 29, 2015 to Duffy et al., both of which are incorporated by reference as if fully set forth herein. The embodiments described herein may be further configured as described in these patents.

The metrology subsystems described herein may be configured to generate output, e.g., images, of the wafer with multiple modes. In general, a “mode” is defined by the values of parameters of the metrology subsystem used for generating output for a wafer. Therefore, modes that are different may be different in the values for at least one of the parameters of the metrology subsystem (other than location at which the output is generated). In this manner, the output may be generated by the metrology subsystem with two or more different values of a parameter of the metrology subsystem. For example, in an optical subsystem, different modes may use different wavelengths of light for illumination. The modes may be different in the illumination wavelengths as described further herein (e.g., by using different light sources, different spectral filters, etc.) for different modes. In another embodiment, different modes may use different illumination channels. For example, as noted above, the metrology subsystem may include more than one illumination channel. As such, different illumination channels may be used for different modes.

In a similar manner, the output generated by the electron beam subsystem may include output, e.g., images, generated by the electron beam subsystem with two or more different values of a parameter of the electron beam subsystem. The multiple modes of the electron beam subsystem can be defined by the values of parameters of the electron beam subsystem used for generating output and/or images for a wafer. Therefore, modes that are different may be different in the values for at least one of the electron beam parameters of the electron beam subsystem. For example, in an electron beam subsystem, different modes may use different angles of incidence for illumination.

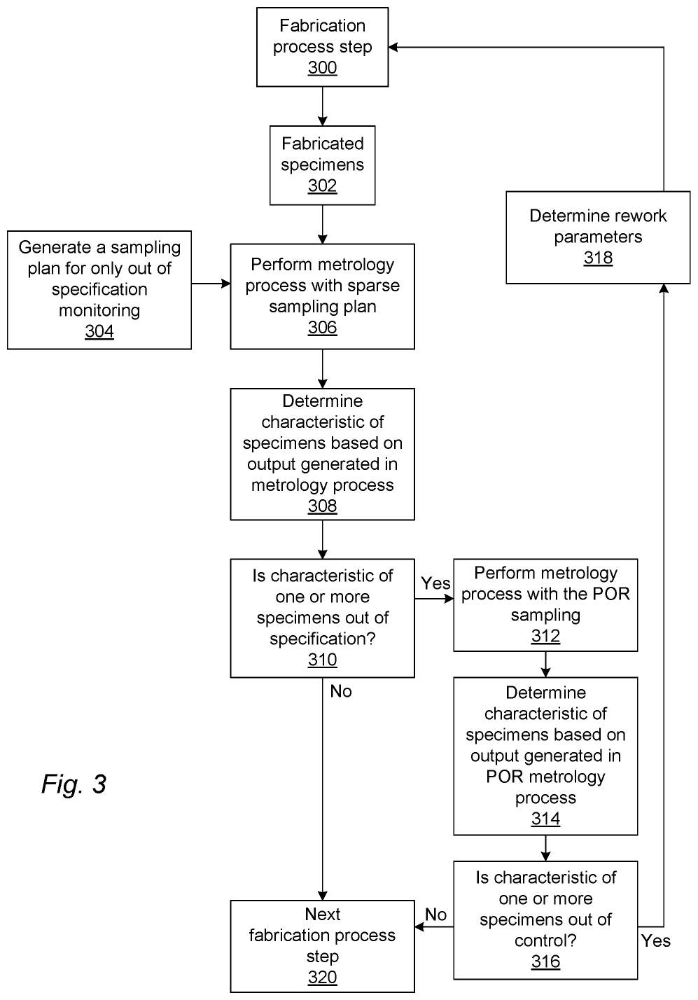

The computer system is configured for generating a sampling plan for only out of specification detection of a characteristic of specimens in a metrology process. For example, as shown in step 304 of FIG. 3, the computer system may generate a sampling plan for only out of specification monitoring. In one embodiment, the sampling plan is not configured for feedback control of the characteristic. Configuring the sampling plan for only out of specification detection and not feedback control may be done in a number of different ways described herein. These embodiments therefore represent a major change over the old methods in that the sampling plan targets only out of specification detection, not overlay feedback control.

The computer system determines the number and locations of the metrology points on the wafer to be used for out of specification detection. For example, the sampling plans generated as described herein will generally include information for which wafers in which lots to measure and where on each wafer the measurements are to be performed. This information may be included in the sampling plan in any suitable manner. For example, the locations at which the measurements are to be performed on the wafers may be expressed in some coordinates, like wafer coordinates, die coordinates, design coordinates, coordinates relative to an alignment mark, and the like. The information for the lots in which wafers are to be measured may be expressed in different ways as well such as lot ID's, information for number or frequency of lots to be measured, e.g., every lot, every other lot, etc., percentage or portion of lots to be measured, and the like. The information for the wafers that are to be measured may also be expressed in a similar manner such as wafer ID's, information for number or frequency of wafers to be measured, e.g., every wafer, every other wafer, etc., percentage or portion of wafers to be measured, and the like.

In one embodiment, a density of the sampling plan is less than a density required to enable feedback control of the characteristic. For example, the embodiments described herein generate and use substantially sparse sampling specifically for only out of specification wafer detection. In particular, the sampling plan for only out of specification monitoring is substantially sparse compared to metrology sampling needed for overlay feedback control. More specifically, the proposed substantially sparse sampling plans for only out of specification detection do not have enough metrology points to perform overlay feedback control based on metrology results generated at the metrology points. For example, the sampling plans generated as described herein may be configured to have only one or two measurement points for each wafer (or a subset of wafers) in each lot. In this manner, the embodiments described herein may be configured for detecting out of specification wafers by performing metrology on a handful of points on each wafer.

In contrast, currently used methods for overlay metrology usually have tens or even hundreds of measurement points on each of a handful of wafers in fewer than all of the lots to thereby prevent this metrology from having a negative impact on throughput of the overall process. Overlay out of specification detection is typically performed using these same results. In this manner, the embodiments described herein perform overlay metrology in an entirely new way compared to currently used methods and systems. In particular, the embodiments described herein are configured for generating a sampling plan for measuring many or all wafers within a lot (each lot) with an extremely sparse sampling plan to maximize out of specification detection.

In an additional embodiment, the sampling plan is configured for generating the output for each of the specimens in a lot. For example, the embodiments described herein provide a sampling method that can detect out of specification wafers within a lot with reduced metrology on each wafer. In a further embodiment, the sampling plan is configured for generating the output for a subset of the specimens in a lot. For example, the computer system may generate the sampling plan so that a subset of wafers in each lot is measured with substantially sparse sampling to detect out of specification wafers. The embodiments described herein ideally measure all wafers within a lot with substantially sparse sampling. If that is not practical or possible, the computer system may determine the number of wafers in the subset based on throughput requirements. The computer system may select a subset of wafers from a lot uniformly, randomly, or based on some known distribution (e.g., if a user or the computer system observes that wafers from a lot processed first or last by the fabrication tool are more likely to fail). In this manner, the sampling methods generated as described herein can detect out of specification lots with reduced metrology on each or a subset of wafers within the lot.

In one embodiment, generating the sampling plan includes selecting a number and coordinates of locations at which the metrology subsystem generates the output in the metrology process to match out of specification criteria for the specimens. For example, the number and location of the metrology points (i.e., the sampling plan) may be selected to match the out of specification criteria used on a given layer and device in a manufacturing process. In this way, the number of out of specification wafers that can be detected and fixed is maximized with the smallest throughput hit.

The computer system may select the number and locations of the metrology points to match the out of specification criteria as described in the following example. The user (e.g., a device manufacturer) may use a statistic such as absolute value of the mean+3*standard deviation of the measured overlay for wafer quality control. For each layer and device, a threshold is defined on the statistic beyond which a wafer or lot would be considered out of specification. If the computer system has access to historical data (e.g., overlay measurements performed with a relatively dense sampling plan on multiple wafers from a given layer and device), the computer system may use one of the existing sampling optimization methods to generate multiple relatively sparse sampling plans. On each wafer, the computer system may calculate the statistic using all originally measured points and then estimate the statistic using the subset of points defined by the optimization method. The sampling plan that tracks the original statistic the best can be selected as the sampling plan for out of specification detection.

In some embodiments, the computer system is configured for determining a metric based on the generated output and a predetermined statistical process control (SPC) metric that separates in specification specimens from out of specification specimens. Such a computer system configuration is optional when historical metrology data is available. For example, the computer system may calculate the metric using metrology collected with the sampling plan generated for only out of specification detection that tracks the existing SPC metric for separating in specification and out of specification wafers. More specifically, users may measure multiple overlay points per wafer and calculate mean and standard deviation of these measurements. A statistic such as absolute value of mean+3*standard deviation is an example of such a metric. The computer system may use the resulting quality control charts to determine how this statistic changes from run-to-run. The computer system may define a threshold on this metric to separate in specification wafers from out of specification wafers. This threshold may be linked to a yield metric for the fabrication process such as yield of electrical tests performed later in the process.

In one such embodiment, the computer system is configured for determining a threshold for the determined metric that separates the in specification specimens from the out of specification specimens. For example, the embodiments described herein may calculate a threshold for out of specification wafer detection on substantially sparse metrology data. Such a computer system configuration is also optional when historical metrology data is available. The computer system may calculate a new threshold on the new metric to separate in specification and out of specification wafers. In one such example, the computer system may track some reference metric (e.g., wafer yield, electrical test, absolute value of mean+3*standard deviation of the dense sampling plan) that is already being used to separate the out of specification wafers from the in specification wafers. The computer system may correlate the metric calculated using a substantially small number of measurements with the reference metric and define the threshold so that the new metric captures all out of specification wafers while minimizing the number of false detections at the same time. This threshold calculation may be in addition to the currently used method in which the same threshold for out of specification detection is usually used independently of the underlying sampling plan.

In another embodiment, generating the sampling plan includes determining a frequency of lot sampling, a frequency of within-lot sampling, within-specimen sampling plans, and metrology subsystem settings based on constraints on metrology budget and metrology subsystem throughput. For example, the computer system may determine the frequency of lot sampling, the frequency of within-lot sampling, and within-wafer sampling plan(s), and tool settings under the constraint of the available metrology budget and required tool throughput. In this manner, the embodiments described herein may be configured for co-optimizing sampling and metrology tool parameters to achieve required throughput. Generating the sampling plan in this manner is an improvement over the currently used methods as it explicitly considers trading off metrology accuracy/precision for tool throughput when distributing metrology budget.

In a further embodiment, generating the sampling plan includes distributing a predetermined metrology budget between lot sampling, specimen sampling, and within-specimen sampling to maximize detection of out of specification specimens. For example, the embodiments described herein provide a sampling system that optimally distributes available metrology budget between lot, wafer, and within-wafer sampling to maximize the number of detected out of specification wafers. The metrology budget may be expressed in a number of different ways such as time allowed for metrology or number of measurements that can be performed without impacting the overall throughput. The allowed time, number of measurements, or other metrology budget specification may then be divided across wafer, lot, and measurement points per wafer to maximize the detection of out of specification specimens. In one such example, the total number of measurements in the predetermined metrology budget may be distributed so that each wafer in each lot is measured even if that means that a substantially limited number of measurement points can be measured on each wafer.

In an additional embodiment, generating the sampling plan includes co-optimizing sampling frequency and metrology subsystem settings to maximize detection of out of specification specimens at a predetermined metrology subsystem throughput. In other words, an important feature of the embodiments described herein is a sampling system that co-optimizes the sampling frequency and metrology tool settings to achieve optimal out of specification detection at the required tool throughput. For example, metrology subsystems such as those described further herein have a number of settings that can be used to tradeoff measurement time and measurement quality. In one such example, a number of image frames may normally be collected during measurement to reduce noise in the measurement or a double image grab may normally be performed instead of a single image grab. These measurement parameters may be examined to determine if they can be modified to reduce the time involved in the measurement with acceptable impact on the measurement results. In the example described above, the computer system may determine if the number of image frames collected can be reduced without causing too much noise in the measurements or if out of specification detection can be performed with only a single image grab instead of a double image grab. In this manner, the computer system can determine the measurement settings that can be used to adequately detect out of specification wafers in the minimum amount of time. Reducing measurement time allows for measurement of more points per wafer and/or more wafers within the lot to detect out of specification wafers.

As shown in step 300, the embodiments described herein or another system or method may perform a fabrication process step on one or more specimens, one or more lots of specimens, etc. This fabrication process step may be a lithography process performed by a lithography tool that includes a scanner or other exposure tool. However, this fabrication process step may vary depending on the characteristic that the embodiments described herein are monitoring. For example, this fabrication process step may be an etch process step performed with an etch tool. Any of these fabrication process steps may be performed in any suitable manner known in the art.

Fabrication process step 300 produces fabricated specimens 302. In general, these fabricated specimens may be wafers having patterned features formed thereon in one of the fabrication process steps described above. However, the fabricated specimens may be any other specimens described herein. As mentioned above, in one embodiment, the characteristic is overlay of one or more first patterned features formed on the specimen to one or more second patterned features formed on the specimen. Generally, “overlay” (sometimes also referred to as “overlay misregistration”) as that term is used herein is defined as the position of first patterned features on a specimen relative to second patterned features on the specimen. The first patterned features and the second patterned features are formed in different process steps, i.e., different lithography process steps. Typically, overlay is determined for patterned features formed on different layers of the specimen, one below the other, although that is not necessary. For example, the embodiments described herein can be configured for out of specification detection of other spatial relationships between patterned features formed on the specimens, e.g., the spatial relationships between different patterned features formed on the same layer with different lithography exposure steps.

The metrology subsystem is configured for generating output for the specimen by performing the metrology process on the specimens with the generated sampling plan. In this manner, the system includes a metrology tool that performs the measurements in accordance with the sampling plan generated by the computer system. As shown in step 306 of FIG. 3, the metrology subsystem may perform a metrology process with a sparse sampling plan generated in step 304. For example, the computer system and/or the metrology subsystem may be configured to use the results of one or more steps described herein to perform the metrology process on the specimens.

In one embodiment, the sampling plan includes information for one or more selected lots, one or more selected specimens within the one or more selected lots, one or more locations on the one or more selected specimens, and one or more metrology subsystem settings for generating the output at the one or more locations, the computer system is configured for sending the information in the sampling plan to the metrology subsystem, and generating the output with the generated sampling plan is based on the information from the computer system. For example, the computer system may communicate to the metrology tool the decision on what lot, wafers within the lot, and sampling points within the wafer that are to be measured and what tool recipe parameters are to be used, all of which may be determined according to any of the embodiments described herein.

In some such embodiments, the computer system may be configured for storing information for the generated sampling plan for use in a metrology process. The computer system may be configured to store the information in a recipe or by generating a recipe for the process in which the sampling plan will be used. A “recipe” as that term is used herein can be generally defined as a set of instructions that can be used by a tool to perform a process on a specimen. In this manner, generating a recipe may include generating information for how a process is to be performed, which can then be used to generate the instructions for performing that process. The embodiments can be used to setup a new process or recipe. The embodiments may also be used to modify an existing process or recipe, whether that is a process or recipe that was used for the specimens or was created for one specimen and is being adapted for another specimen.

The information for the sampling plan that is stored by the computer system may include any information that can be used to identify and/or use the sampling plan (e.g., such as a file name and where it is stored, and the file may include information for the sampling plan such as information for wafers to be measured, lots to be measured, locations on wafers to be measured, etc.). The computer system may be configured for storing the information for the sampling in any suitable computer-readable storage medium. The information may be stored with any of the results described herein and may be stored in any manner known in the art. The storage medium may include any storage medium described herein or any other suitable storage medium known in the art. After the information has been stored, the information can be accessed in the storage medium and used by any of the method or system embodiments described herein, formatted for display to a user, used by another software module, method, or system, etc. For example, the embodiments described herein may generate a metrology recipe as described above. That metrology recipe may then be stored and used by the system or method (or another system or method) to perform a metrology process on the specimens to thereby generate information (e.g., measured characteristics) for the specimens.

The computer system is configured for determining the characteristic of the specimens based on the generated output, as shown in step 308, and detecting if the characteristics of one or more of the specimens is out of specification based on the determined characteristic of the specimens, as shown in step 310. For example, the computer system may receive the metrology data from the metrology tool and determine the characteristic from the metrology data. The computer system may determine the characteristic of the specimens using any suitable metrology method or algorithm known in the art. In general for overlay measurements, such an algorithm may be configured for identifying different patterned features in one or more images generated by the metrology subsystem and determining a spatial relationship between the different patterned features based on, for example, a distance between the features in the image(s) and dimensions of pixels in the image(s). The computer system may detect if the characteristic is out of specification by applying a metric or threshold determined as described herein to the determined characteristic to make a decision what lots and/or wafers are out of specification.

In one embodiment, the metrology subsystem is configured for generating additional output for at least one of the specimens by performing an additional metrology process on the at least one of the specimens with a different sampling plan suitable for feedback control of the characteristic, and the computer system is configured for determining a correction process for the at least one of the specimens based on the generated additional output. The different sampling plan suitable for feedback control of the characteristic may be any currently used sampling plan capable of providing measurements sufficient for feedback control of the characteristic. Metrology performed using such a sampling plan may be performed as described further herein or in any other suitable manner known in the art. The computer system may determine the correction process as described further herein or in any suitable manner known in the art.

In one such example, in step 306, the metrology process is performed with a substantially sparse sampling plan to measure, for example, a subset (or all) of the wafers in each lot to detect out of specification wafers. This metrology is performed independently of, and possibly in addition to, a metrology process with the process of record (POR) sampling plan designed for supporting stability of the advanced process control (APC). In this manner, the embodiments described herein provide a sampling method for out of specification wafer monitoring and rework decisions. In addition, the embodiments described herein provide a sampling system that separates overlay control from out of specification detection and rework decisions. This out of specification targeted metrology may be performed in addition to metrology designed for APC.

In another embodiment, the computer system is configured for selecting at least one of the one or more of the specimens detected to be out of specification for which the metrology process is performed with a denser sampling plan than the generated sampling plan. In another such embodiment, the denser sampling plan is configured for feedback control of the characteristic. For example, the computer system may receive the metrology data from the metrology tool and may use a metric or threshold determined as described herein to determine which lots and/or wafers are out of specification and whether they should be remeasured with a denser (e.g., POR) sampling to determine rework correction. As shown in step 312 of FIG. 3, when the computer system determines that one or more specimens are out of specification, the metrology subsystem may perform a metrology process with the POR sampling on at least one of those specimens. In this manner, because the sampling plans are generated herein for out of specification detection and not feedback control, the measurements generated with those sampling plans cannot be used to determine rework correction or other suitable feedback control parameters. Therefore, performing metrology with denser, POR sampling for any one or more specimens detected to be out of specification may enable determining if one or more parameters of the lithography process should be altered and how they should be altered.

The denser sampling plan used for feedback control of the characteristic may be a predetermined sampling plan, e.g., a POR sampling plan, which may be generated by the computer system or another system or method and accessible to the embodiments described herein. A “denser” sampling plan may be defined as simply denser than the sampling plans generated as described herein for only out of specification detection. For example, a “denser” sampling plan may be configured for measuring tens or even hundreds of measurement points on a handful of specimens or lots.

The computer system described herein may therefore use a predetermined denser sampling plan for feedback control. However, the computer system may in some embodiments be configured for generating the denser sampling plan, for example, based on any of the results described herein. For example, when a specimen is determined to be out of specification for the characteristic, a denser sampling plan may be generated by the computer system based on how far out of specification the characteristic is. In one such example, if the characteristic of one or more specimens is determined to be substantially far out of specification, the denser sampling plan may include measuring a greater number of measurement points on more specimens than if the characteristic of the one or more specimens is determined to be only slightly out of specification. Any suitable relationship between the degree to which a characteristic is out of specification and a density of the sampling plans for feedback control may be used by the computer system to determine the denser sampling plan. The relationship may be based on, for example, historical data, theoretical models or information for the process, etc.

In this manner, the embodiments described herein may be configured for performing out of specification detection using the sampling plan generated as described herein and selecting specimens for APC type monitoring based on the results of the out of specification detection. However, this sequence of metrology processes may be modified in some situations. In one such example, the sampling plan generated as described herein may include information for which specimens are to be sent to POR metrology for APC and which specimens are to be sent to out of specification detection. In this manner, a first subset of specimens may be sent to APC metrology, a second subset may be sent to out of specification metrology, and the different subsets may be predetermined and not based on the results of either metrology process. In some such instances, APC metrology and out of specification metrology may be performed with the same metrology subsystem and in the same metrology process (e.g., while a lot is loaded into the metrology tool) but other variations are possible such as performing the different metrology with different metrology tools, in different processes, etc.

In one such embodiment, the computer system is configured for determining a correction process for the at least one of the one or more of the specimens based on the output generated with the denser sampling plan. For example, the computer system may determine a characteristic of the specimens based on output generated in the POR metrology process, as shown in step 314 of FIG. 3. The computer system may determine the characteristic based on the POR metrology process output in any suitable manner known in the art. The computer system may also determine if the characteristic of one or more specimens is out of control in step 316 of FIG. 3. Determining if the characteristic of the one or more specimens is out of control may include applying a threshold to the determined characteristic and determining that a specimen is out of control when the determined characteristic is above this threshold (or below the threshold depending on the characteristic and the threshold value). The threshold may be a SPC threshold determined as described further herein.

When the computer system determines that the characteristic of one or more specimens is out of control, the computer system may determine rework parameters in step 318. The determined rework parameters and the one or more specimens having a characteristic that is out of control may then be sent back to fabrication process step 300. For example, if the characteristic is determined to be out of control limits, the computer system may determine if the characteristic of the out of control specimen(s) can be remedied by changing one or more parameters of the fabrication process step or tool and then performing the process again on the specimens with the altered parameters. In one such example, after lithography is performed, it may be possible to strip the patterned features formed by lithography from the specimen, e.g., using an etch process, a polishing process, etc. The lithography may then be reperformed on the specimen with the new process parameters. Determining the rework parameters may include determining any of the parameters involved in re-forming the patterned features on the specimen, including any parameters of any stripping process, any new parameters of the lithography process etc. Determining the rework parameters may be performed using any suitable predetermined relationship between process parameters and specimen characteristics.

Whether or not rework parameters are determined by the embodiments described herein may depend on the process that was performed on the specimens. For example, not all manufacturing processes may be reworked or reworking some manufacturing processes may simply be impractical. One such example is an etch process. If the fabrication process step is an etch process, detecting out of specification specimens and/or out of control specimens is still beneficial. For example, such wafers and/or lots may be scrapped rather than proceeding to the next fabrication process step, thereby avoiding spending time and money on wafers that will have to be scrapped anyway.

When the characteristic of the specimens is not determined to be out of specification in step 310 and/or the characteristic of the specimens is not determined to be out of control in step 316, the specimens may be sent to the next fabrication process step in step 320. In other words, when the specimens are determined to be acceptable, e.g., not out of specification and/or within control limits, the specimens may be sent to the next fabrication process step. In one such example, if fabrication process step 300 is a lithography process, then fabrication process step 320 may be an etch process. In another such example, if fabrication process step 300 is an etch process, then fabrication process step 320 may be a deposition step.

The computer system may be configured for generating results for the specimens, which may include any of the information described herein such as the determined characteristics, whether any of the specimens are out of specification, which specimens are out of specification, rework parameters, etc. The results for the specimens may be generated by the computer system in any suitable manner. In addition, the results for the specimens may be stored as described further herein and used to perform one or more functions for the specimens or other specimens of the same type.

Such functions include, but are not limited to, altering a process such as a fabrication process or step that was or will be performed on the specimens in a feedback or feedforward manner, etc. For example, as described further herein, the computer system may be configured to determine one or more changes to a process that was performed on the specimens and/or a process that will be performed on the specimens based on the determined characteristic. The changes to the process may include any suitable changes to one or more parameters of the process. The computer system preferably determines those changes such that any out of control characteristic can be prevented on other specimens on which the revised process is performed, any out of control characteristic can be corrected or eliminated on the specimens in another process performed on the specimens, any out of control characteristic can be compensated for in another process performed on the specimens, etc. The computer system may determine such changes in any suitable manner known in the art.

Those changes can then be sent to a semiconductor fabrication system (not shown) or a storage medium (not shown) accessible to both the computer system and the semiconductor fabrication system. The semiconductor fabrication system may or may not be part of the system embodiments described herein. For example, the metrology subsystem and/or the computer system described herein may be coupled to the semiconductor fabrication system, e.g., via one or more common elements such as a housing, a power supply, a specimen handling device or mechanism, etc. The semiconductor fabrication system may include any semiconductor fabrication system known in the art such as a lithography tool, an etch tool, a chemical-mechanical polishing (CMP) tool, a deposition tool, and the like.

The embodiments described herein have a number of important advantages over the currently used methods for out of specification metrology. For example, the embodiments described herein are configured to enable capture and rework of more out of specification lots at a relatively low metrology cost and avoid yield loss. In another example, the embodiments described herein enable capture and rework of more out of specification wafers within a lot at a relatively low metrology cost and avoid yield loss. In an additional example, the embodiments described herein enable avoiding unnecessary work by measuring more wafers within a lot at a relatively low metrology cost. The embodiments described herein can also avoid degradation of good lots due to unnecessary rework. Furthermore, the embodiments described herein enable co-optimizing metrology tool settings and sampling to achieve the required throughput and out of specification detection accuracy.

The advantages of the embodiments described herein over currently used metrology systems and methods are provided by a number of new features of the embodiments described herein including, but not limited to, a sampling method and system for only out of specification wafer monitoring and rework decisions. Another new feature of the embodiments described herein is a sampling system that separates overlay control from out of specification detection and rework decisions. An additional new feature of the embodiments described herein is a sampling method that can detect out of specification lots with reduced metrology on a subset of wafers within the lot. A further new feature includes a sampling method that can detect out of specification wafers within a lot with reduced metrology on each wafer. The new features also include a sampling system that optimally distributes available metrology budget between lot, wafer, and within-wafer sampling to maximize the number of detected out of specification wafers. Yet another new feature is a sampling system that co-optimizes the sampling frequency and metrology tool settings to achieve optimal out of specification detection at the required tool throughput.

Each of the embodiments of each of the systems described above may be combined together into one single embodiment.

Another embodiment relates to a computer-implemented method for determining information for a specimen. The method includes generating a sampling plan for only out of specification detection of a characteristic of specimens in a metrology process, as shown in step 304 of FIG. 3. The method also includes generating output for the specimens by performing the metrology process on the specimens with a metrology subsystem and the generated sampling plan, as shown in step 306. In addition, the method includes determining the characteristic of the specimens based on the generated output, as shown in step 308. The method further includes detecting if the characteristic of one or more of the specimens is out of specification based on the determined characteristic of the specimens, as shown in step 310. Generating the sampling plan, determining the characteristic, and the detecting step are performed by a computer system (e.g., computer subsystem 36 and/or computer subsystem(s) 102 shown in FIG. 1) coupled to the metrology subsystem (e.g., metrology subsystem 10).

Each of the steps of the method may be performed as described further herein. The method may also include any other step(s) that can be performed by the system, computer system, and/or metrology subsystem described herein. The computer system and the metrology subsystem may be configured according to any of the embodiments described herein, e.g., computer subsystem 36 and/or computer subsystem(s) 102 and metrology subsystem 10, respectively. In addition, the method described above may be performed by any of the system embodiments described herein.

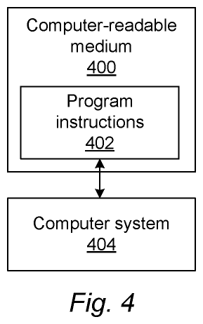

An additional embodiment relates to a non-transitory computer-readable medium storing program instructions executable on a computer system for performing a computer-implemented method for determining information for a specimen. One such embodiment is shown in FIG. 4. In particular, as shown in FIG. 4, non-transitory computer-readable medium 400 includes program instructions 402 executable on computer system(s) 404. The computer-implemented method may include any step(s) of any method(s) described herein.

Program instructions 402 implementing methods such as those described herein may be stored on computer-readable medium 400. The computer-readable medium may be a storage medium such as a magnetic or optical disk, a magnetic tape, or any other suitable non-transitory computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), SSE (Streaming SIMD Extension) or other technologies or methodologies, as desired.

Computer system(s) 404 may be configured according to any of the embodiments described herein.

Further modifications and alternative embodiments of various aspects of the invention will be apparent to those skilled in the art in view of this description. For example, methods and systems for determining information for a specimen are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

1. A system configured for determining information for specimens, comprising:
a computer system configured for generating a sampling plan for only out of specification detection of a characteristic of specimens in a metrology process; and
a metrology subsystem configured for generating output for the specimens by performing the metrology process on the specimens with the generated sampling plan;
wherein the computer system is further configured for determining the characteristic of the specimens based on the generated output and detecting if the characteristic of one or more of the specimens is out of specification based on the determined characteristic of the specimens.

2. The system of claim 1, wherein the characteristic is overlay of one or more first patterned features formed on the specimen to one or more second patterned features formed on the specimen.

3. The system of claim 1, wherein the sampling plan is not configured for feedback control of the characteristic.

4. The system of claim 1, wherein a density of the sampling plan is less than a density required to enable feedback control of the characteristic.

5. The system of claim 1, wherein the sampling plan is configured for generating the output for each of the specimens in a lot.

6. The system of claim 1, wherein the sampling plan is configured for generating the output for a subset of the specimens in a lot.

7. The system of claim 1, wherein generating the sampling plan comprises selecting a number and coordinates of locations at which the metrology subsystem generates the output in the metrology process to match out of specification criteria for the specimens.

8. The system of claim 1, wherein the computer system is further configured for determining a metric based on the generated output and a predetermined statistical process control metric that separates in specification specimens from out of specification specimens.

9. The system of claim 8, wherein the computer system is further configured for determining a threshold for the determined metric that separates the in specification specimens from the out of specification specimens.

10. The system of claim 1, wherein generating the sampling plan comprises determining a frequency of lot sampling, a frequency of within-lot sampling, within-specimen sampling plans, and metrology subsystem settings based on constraints on metrology budget and metrology subsystem throughput.

11. The system of claim 1, wherein generating the sampling plan comprises distributing a predetermined metrology budget between lot sampling, specimen sampling, and within-specimen sampling to maximize detection of out of specification specimens.

12. The system of claim 1, wherein generating the sampling plan comprises co-optimizing sampling frequency and metrology subsystem settings to maximize detection of out of specification specimens at a predetermined metrology subsystem throughput.

13. The system of claim 1, wherein the sampling plan comprises information for one or more selected lots, one or more selected specimens within the one or more selected lots, one or more locations on the one or more selected specimens, and one or more metrology subsystem settings for generating the output at the one or more locations, wherein the computer system is further configured for sending the information in the sampling plan to the metrology subsystem, and wherein generating the output with the generated sampling plan is based on the information from the computer system.

14. The system of claim 1, wherein the metrology subsystem is further configured for generating additional output for at least one of the specimens by performing an additional metrology process on the at least one of the specimens with a different sampling plan suitable for feedback control of the characteristic, and wherein the computer system is further configured for determining a correction process for the at least one of the specimens based on the generated additional output.

15. The system of claim 1, wherein the computer system is further configured for selecting at least one of the one or more of the specimens detected to be out of specification for which the metrology process is performed with a denser sampling plan than the generated sampling plan.

16. The system of claim 15, wherein the computer system is further configured for determining a correction process for the at least one of the one or more of the specimens based on the output generated with the denser sampling plan.

17. The system of claim 15, wherein the denser sampling plan is configured for feedback control of the characteristic.

18. The system of claim 1, wherein the metrology subsystem is further configured as a light-based metrology subsystem.

19. A non-transitory computer-readable medium, storing program instructions executable on a computer system for performing a computer-implemented method for determining information for a specimen, wherein the computer-implemented method comprises:
generating a sampling plan for only out of specification detection of a characteristic of specimens in a metrology process;
generating output for the specimens by performing the metrology process on the specimens with the generated sampling plan;
determining the characteristic of the specimens based on the generated output; and
detecting if the characteristic of one or more of the specimens is out of specification based on the determined characteristic of the specimens.

20. A computer-implemented method for determining information for a specimen, comprising:
generating a sampling plan for only out of specification detection of a characteristic of specimens in a metrology process;
generating output for the specimens by performing the metrology process on the specimens with a metrology subsystem and the generated sampling plan;
determining the characteristic of the specimens based on the generated output; and
detecting if the characteristic of one or more of the specimens is out of specification based on the determined characteristic of the specimens, wherein generating the sampling plan, said determining, and said detecting are performed by a computer system coupled to the metrology subsystem.
